(19) United States
(12) Patent Application Publication
(10) Pub. No.: US 2005/0164624 A1
(43) Pub. Date: Jul. 28, 2005

(54) Electronic apparatus

(76) Inventor: Kenichi Hisamatsu, Ome-shi (JP)

Correspondence Address: BLAKELY SOKOLOFF TAYLOR & ZAFMAN, 12400 WILSHIRE BOULEVARD, SEVENTH FLOOR, LOS ANGELES, CA, 90025-1030, US

(21) Appl. No.: 11/011,871

(22) Filed: Dec. 14, 2004

(30) Foreign Application Priority Data
Dec. 26, 2003 (JP) 2003-432834

(51) Int. Cl. H05K 5/00

(52) U.S. Cl. 454/184

(57) ABSTRACT

According to one embodiment of the invention, an electronic apparatus includes a housing and an air-blowing unit. The housing has a first wall on which a first ventilation portion is provided, and a second wall on which a second ventilation portion is provided. The second wall intersects the first wall. The housing can be installed in a first state allowing the first wall to face upward or a second state allowing the second wall to face upward. The air-blowing unit can blow air in a first air-blowing direction from a side of the second ventilation portion to a side of the first ventilation portion when the housing is in the first state. The air-blowing unit further blows air in a second air-blowing direction from a side of the first ventilation portion to a side of the second ventilation portion, when the housing is in the second state.

### CROSS-REFERENCE TO RELATED APPLICATIONS

This application is based upon and claims the benefit of priority from prior Japanese Patent Application No. 2003-432834, filed Dec. 26, 2003, the entire contents of which are incorporated herein by reference.

### BACKGROUND

1. Field

Embodiments of the invention generally relate to an electronic apparatus such as a personal computer.

2. Description of the Related Art

Jpn. Pat. Appln. KOKAI Publication No. 10-261884 discloses an information processing apparatus comprising a housing which can be installed transversely or longitudinally, a heat generating member provided in the housing, a forced-air cooling fan, a sensor which senses the installation of the information processing apparatus when it is installed longitudinally, and a control circuit which stops rotation of the fan by the sensing of the sensor.

More specifically, the housing comprises an air inlet hole, an exhaust hole, and an air intake for forced-air cooling. The air inlet hole is formed at a position regarded as a lower side portion of the housing when the apparatus is installed longitudinally. The exhaust hole is formed at a position regarded as a top surface of the housing when the apparatus is installed longitudinally. The air intake is formed on a portion of the housing which faces the fan.

When the apparatus is installed transversely, the fan is operated to perform forced-air cooling. At this time, the air inlet hole serves as the exhaust hole. In other words, air enters the housing from the air inlet hole by suction force of the fan, cools the heat generating member provided inside the housing, and flows out of the housing from the exhaust hole and the air inlet hole.

When the apparatus is installed longitudinally, however, the control circuit senses the longitudinal installation of the apparatus by a signal from the sensor and stops the fan. In this case, air heated by the heat-generating unit moves upward. For this reason, the air entering the housing from the air inlet hole provided at the lower portion of the housing and the air intake moves upward inside the housing so as to generate natural convection that the air flows out of the housing from the exhaust hole formed at the upper portion of the housing. The heat generating member is cooled by the natural convection.

Incidentally, the increased demand for higher processing speed and multifunction of an electronic component, such as a CPU for example, have caused heat dissipation concerns. Higher integration and higher performance of the CPU employed in such an electronic apparatus tend to increase the amount of heat generated. For this reason, when the housing accommodates a heat-generating unit such as a CPU generating a large amount of heat, further improvements of radiation of the heat-generating unit inside the housing may be required.

According to the invention of the above-identified Japanese patent publication, however, when the apparatus is installed longitudinally, radiation of the heat generating member (heat-generating unit) is performed by natural convection of air. However, the radiation effect may not provide sufficient heat dissipation, especially as CPU performance increases.

### BRIEF DESCRIPTION OF THE SEVERAL VIEWS OF THE DRAWING

FIG. 1 is an exemplary front view showing a main unit installed in a first state, in a computer according to a first embodiment of the present invention;

FIG. 2 is an exemplary top view showing the main unit of the computer in FIG. 1 installed in the first state;

FIG. 3 is an exemplary cross-sectional view showing a part of the main unit of the computer in FIG. 1;

FIG. 4 is an exemplary side view showing an angle sensor of the computer in FIG. 1;

FIG. 5 is an exemplary front view showing the angle sensor of the computer in FIG. 1;

FIG. 6 is an exemplary block diagram showing a control system of a motor-operated fan of the computer in FIG. 1;

FIG. 7 is an exemplary perspective view showing the main unit of the computer in FIG. 1 installed in the first state;

FIG. 8 is an exemplary front view showing the main unit of the computer in FIG. 1 installed in a second state;

FIG. 9 is an exemplary perspective view showing the main unit of the computer in FIG. 1 installed in the second state;

FIG. 10 is an exemplary cross-sectional view showing a part of the main unit of the computer according to a second embodiment of the present invention;

FIG. 11 is an exemplary cross-sectional view showing a part of the main unit of the computer according to a third embodiment of the present invention, illustrating attachment of a fan in a first direction; and

FIG. 12 is an exemplary cross-sectional view showing a part of the main unit of the computer in FIG. 11, illustrating attachment of a fan in a second direction.

### DETAILED DESCRIPTION

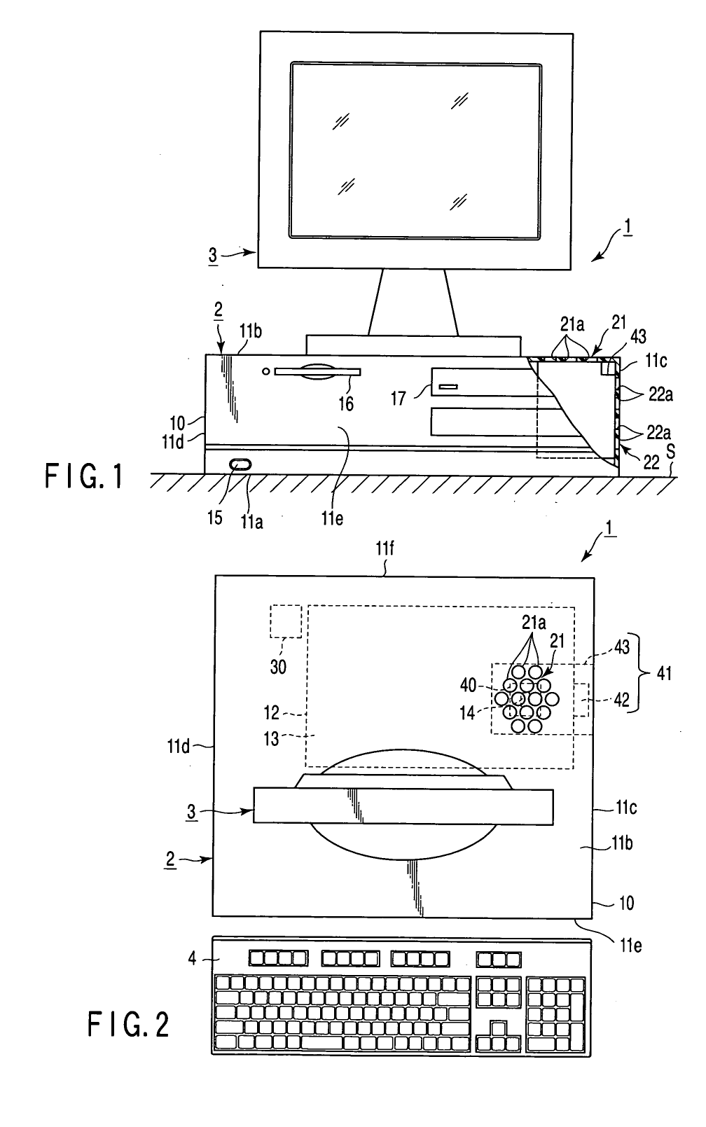

A computer serving as an electronic apparatus, according to a first embodiment of the present invention, will be described with reference to FIGS. 1 to 9.

A computer 1 comprises a main unit 2, a display 3, a keyboard 4 and the like. Both the display 3 and the keyboard 4 are electrically connected to the main unit 2. The main unit 2 comprises a housing 10 shaped in a flat box (flat rectangular parallelepiped) according to this embodiment.

FIGS. 1 and 2 show an example of installing the housing 10 of the computer 1 in a transversely installed implementation (e.g., a first state to be described later). FIG. 8 shows an example of installing the housing 10 in a longitudinally installed implementation (e.g., a second state to be described later).

To describe in detail, the housing 10 has a bottom wall 11a of a lower side in the transversely installed implementation, a top wall 11b serving as a first wall, of a top side in the transversely installed implementation, a side wall 11c serving as a second wall extending from a side edge of the top wall 11b in a direction of intersecting the top wall 11b, for example, in an orthogonal and downward direction, a side wall lid extending from the other side edge of the top wall 11b in a direction of intersecting the top wall 11b, for example, in an orthogonal and downward direction, a front wall 11e extending from a front edge of the top wall 11b in a direction of intersecting the top wall 11b, for example, in an orthogonal and downward direction, and a rear wall 11f extending from a rear edge of the top wall 11b in a direction of intersecting the top wall 11b, for example, in an orthogonal and downward direction. The sidewall 11c serving as the second wall is positioned on a right side, for example, in the transversely installed state. In the following descriptions, the sidewall 11c is called a right sidewall and the sidewall 11d opposite to the right wall 11c is called a left sidewall.

An outer surface of the bottom wall 11a is a substantially flat installation surface. Thus, the housing 10 can be installed on a surface S such as a top plate of a desk while being at the first state or the transversely installed implementation having the top surface 11b facing upward. An outer surface of the top surface 11b is a horizontal support surface. For example, a device such as the display 3 (e.g., liquid crystal display) can be placed on the support surface (FIG. 1).

An outer surface of the left sidewall 11d is also a substantially flat installation surface. Thus, the housing 10 can be installed on a surface S such as a top plate of a desk while the housing 10 is in the second state or the transversely installed implementation having the right sidewall 11c facing upward (FIG. 8).

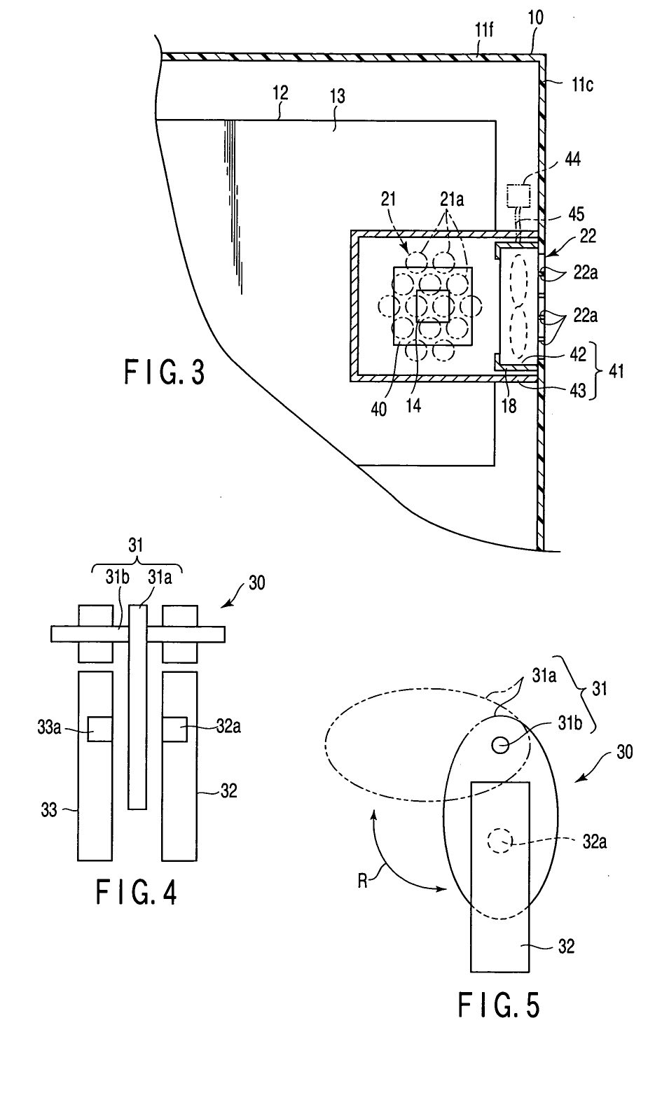

The housing 10 includes a mounting area. The housing 10 accommodates a control circuit 12 serving as a control unit as shown in FIGS. 2 and 3. As shown, the housing 10 also accommodates a power supply unit, a floppy disk drive, a hard disk drive, a CD-ROM drive, as well as one or more connectors (not shown).

The control circuit 12 comprises a circuit board 13 and a number of circuit components mounted on the circuit board 13 as shown in FIGS. 2 and 3. The circuit components include a CPU 14, which is a heat-generating unit. The circuit board 13 is arranged horizontally along the bottom wall 11a and fastened to the housing 10.

Each of the power supply unit, the floppy disk drive, the hard disk drive, the CD-ROM drive and the connector is supported on the housing 10 and electrically connected to the control circuit 12.

A power supply switch 15 configured to turn on and off the power supply unit is exposed to the outside through the front wall lie as shown in FIGS. 1 and 8. For this reason, turning on and off the power supply unit can be controlled outside the housing 10 by operating the power supply switch 15. The floppy disk drive and the CD-ROM drive are arranged near the front wall 11e. A first disk insertion portion 16 connected to the floppy disk drive and a second disk insertion portion 17 connected to the CD-ROM drive are provided on the front wall 11e. The power supply connector, and a plurality of connectors for connection of various kinds of peripheral devices (e.g., a printer, etc.) may be arranged along the rear wall 11f. These connectors are exposed to the outside through the rear wall 11f. For this reason, the power supply cable and the cables connected to the peripheral devices can be connected to the connectors.

For example, if the housing 10 is composed of the base portion having the bottom wall 11a and a cover comprising the top wall 11b, the sidewall 11c, the sidewall 11d, the front wall 11e and the rear wall 11f, the mounting area can be opened as occasion requires.

A first ventilation portion 21 is provided near the right sidewall 11c, on the top wall 11b as shown in FIGS. 1 to 3 and FIGS. 7 to 9. The first ventilation portion 21 comprises a plurality of apertures 21a as ventilation holes. Incidentally, the top surface of the top wall 11b is the support surface, which supports the display 3 (e.g., liquid crystal display) or the like as explained above. Thus, the first ventilation portion 21 may be provided along the top wall 11b near the rear wall 11f rather than around the middle of the top wall 11b. This prevents the apertures 21a from being covered by a stand of the display 3 when mounted on the top surface of the top wall 11b.

On the other hand, a second ventilation portion 22 is provided on the right sidewall 11c as shown in FIGS. 1 and 7 to 9. The second ventilation portion 22 comprises a plurality of apertures 22a as ventilation holes. The second ventilation portion 22 is provided near the rear wall 11f rather than around the middle of the right sidewall 11c.

The main unit 2 comprises an angle sensor 30, which determines the transversely installed implementation from the longitudinally installed implementation as shown in FIGS. 2, 4 and 5. The angle sensor 30 is affixed to the housing 10 and electrically connected to the control circuit 12. As the angle sensor 30, for example, a photo-interrupter comprises a shielding unit 31, a light-emitting unit 32 and a light-receiving unit 33. FIGS. 4 and 5 show a state of the angle sensor 30 in a case where the housing 10 is installed transversely.

The shielding unit 31 comprises a shielding plate 31a having an approximately ellipsoidal shape and a rotary shaft 31b. The rotary shaft 31b is approximately parallel to the front wall lie. The rotary shaft 31b extends in an axial direction through an end portion of the shielding plate 31a. Thus, the shielding plate 31a rotates about the rotary shaft 31b at approximately 90 degrees as represented by an arrow R in FIG. 5, under its own weight, when the housing 10 is in the transversely installed implementation or the longitudinally installed implementation.

In other words, according to this embodiment of the invention, the shielding plate 31a is at a position represented by a solid line in FIG. 5 when the housing 10 is in the transversely installed implementation. When the housing 10 is in the longitudinally installed implementation, however, the shielding plate 31a rotates about the rotary shaft 31b at approximately 90 degrees under its own weight and moves to a position represented by a dashed chain line in FIG. 5.

The light-emitting unit 32 comprises a light source unit 32a. The light-emitting unit 32 is arranged to be opposite to one of surfaces of the shielding plate 31a when the housing 10 is in the transversely installed implementation. The light-receiving unit 33 comprises a sensing unit 33a configured to sense the light beam emitted from the light source unit 32a, for example, a photo-transistor. The light-receiving unit 33 is arranged so that the sensing unit 33a is opposite from the light source unit 32a. The shielding plate 31a is interposed between the light-receiving unit 33 and the light-emitting unit 32 when the housing 10 is in the transversely installed implementation.

The angle sensor 30 has the following action. When the housing 10 is in the transversely installed implementation, the shielding plate 31a is at the position represented by the solid line in FIG. 5. The light beam emitted from the light source unit 32a is shielded by the shielding plate 31a and does not reach the sensing unit 33a. On the other hand, when the housing 10 is in the longitudinally installed implementation, the shielding plate 31a moves to the position represented by the two-dot-chained line in FIG. 5 under its own weight. The light beam emitted from the light source unit 32a is not shielded by the shielding plate 31a and reaches the sensing unit 33a.

In other words, the angle sensor 30 senses the implementation of the housing 10 in accordance with whether the light beam emitted from the light source unit 32a of the light-emitting unit 32 is sensed by the sensing unit 33a of light-receiving unit 33. However, the angle sensor 30 is not limited to this particular embodiment, and may be arranged so that the light beam is disrupted when the housing 10 is in the longitudinally installed implementation.

As shown in FIGS. 2 and 3, a heat sink 40 thermally connected to the CPU 14 and a cooling unit 41 configured to forcefully cool the heat sink 40 are arranged inside the housing 10. The heat sink 40 is formed of a metal of high heat conductivity. The heat sink 40 has a plurality of radiating fins (not shown) so as to increase a surface area.

The cooling unit 41 comprises a fan 42 serving as an air-blowing unit and a duct 43. In FIG. 3, reference numeral 44 denotes a power supply connector configured to supply power to the fan 42 via a cable 45. The connector 44 is electrically connected to the control circuit 12. A plug (not shown) connected to the connector 44 is provided at an end of the cable 45.

The fan 42 is arranged to face the second ventilation portion 22 provided on the right sidewall 11c, inside the housing 10. For example, the fan 42 is supported by a supporting member 18 provided on an inner surface of the right sidewall 11c. The fan 42 is also connected electrically to the control circuit 12. For example, the fan 42 may be arranged to face the first ventilation portion 21 provided on the top wall 11b.

The duct 43 is provided to make the first ventilation portion 21 and the second ventilation portion 22 communicate with each other as well shown in FIGS. 1 and 7 to 9. The duct 43 contains the CPU 14, the heat sink 40 and the fan 42 as shown in FIG. 3.

Thus, the heat emitted from the CPU 14 is transmitted to the heat sink 40 and radiated to air. The heated air flows inside the duct 43 and is radiated to the outside of the housing 10 via the first ventilation portion 21 and the second ventilation portion 22.

Incidentally, to rapidly radiate the air heated by the heat from the CPU 14 to the outside of the housing 10, it is contemplated that the fan 42 may be operated to make the air inside the duct 43 flow from the lower side to the upper side.

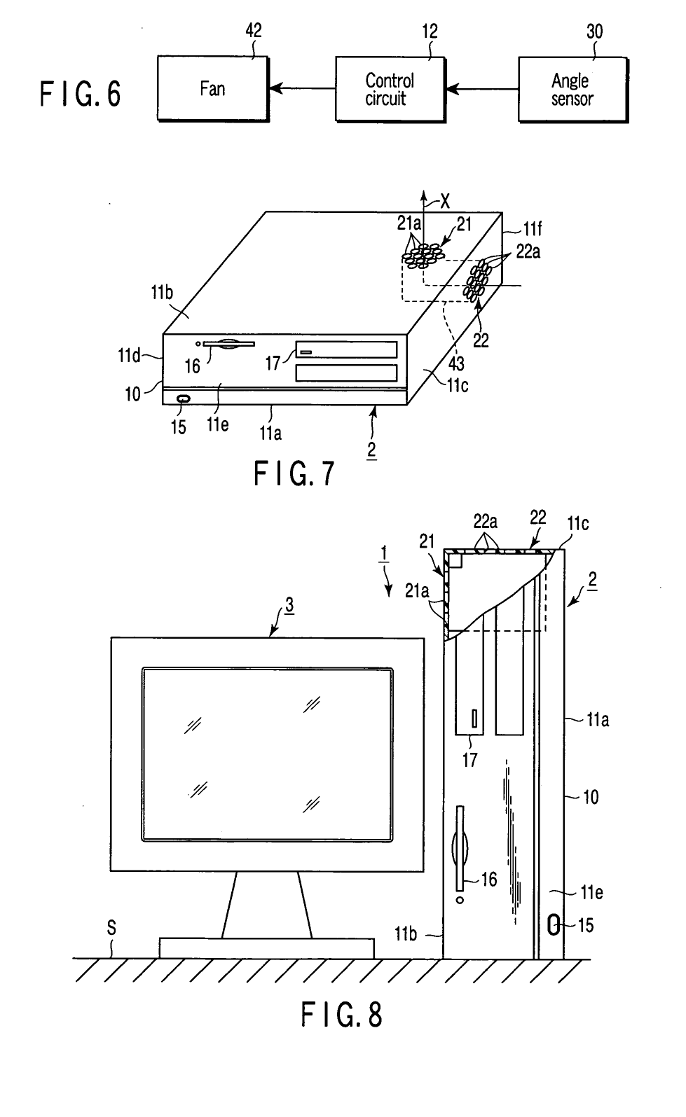

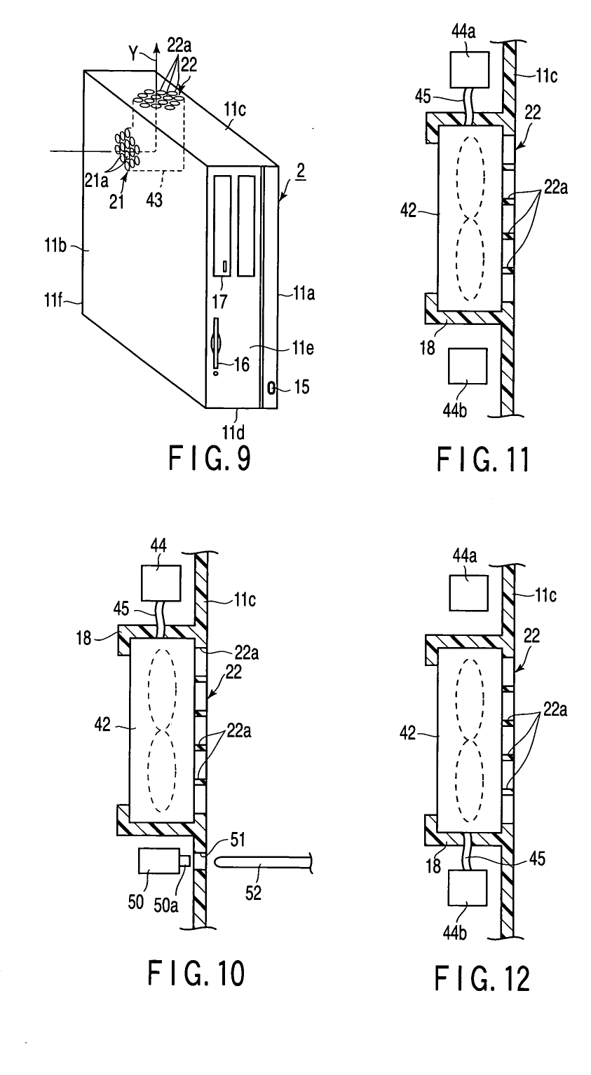

In other words, when the housing 10 is transversely installed such that the top wall 11b faces upward, it is contemplated that the air inside the duct 43 flows in a direction represented by an arrow X in FIG. 7, namely a first air-blowing direction to blow the air from the second ventilation portion 22 side to the first ventilation portion 21 side. On the other hand, when the housing 10 is longitudinally installed such that the right sidewall 11c faces upward, it is possible to make the air inside the duct 43 flow in a direction represented by an arrow Y in FIG. 9 (e.g., a second air-blowing direction to blow the air from the first ventilation portion 21 side to the second ventilation portion 22 side).

For this reason, the present invention employs the fan 42, which is capable of blowing the air inside the duct 43, in the first air-blowing direction from the second ventilation portion 22 side to the first ventilation portion 21 side and the second air-blowing direction from the first ventilation portion 21 side to the second ventilation portion 22 side. The fan 42 is further capable of rotating in a first rotating direction to blow the air in the first air-blowing direction, and a second rotating direction to blow the air in the second air-blowing direction.

In the main unit 2, the control circuit 12 also serves as a control unit configured to change the rotating direction of the fan 42. In other words, the rotating direction of the fan 42 is controlled by the control circuit 12 based on information about the implementation of the housing 10 as sensed by the angle sensor 30.

In the main unit 2, the CPU 14 is cooled in the following manners (FIG. 6).

The heat emitted from the CPU 14 is transmitted to the heat sink 40 and radiated to air. When the temperature of the air in the vicinity of the CPU 14 becomes higher than a predetermined temperature, the implementation of the housing 10 is sensed by the angle sensor 30.

If the housing 10 is transversely installed, the angle sensor 30 senses the installation condition of the housing 10 and transmits the information to the control circuit 12. The control circuit 12 rotates the fan 42 in the first rotating direction such that the air inside the duct 43 flows in the first air-blowing direction (e.g., the direction represented by the arrow X in FIG. 7). In this case, the second ventilation portion 22 serves as the air inlet portion and the first ventilation portion 21 serves as the exhaust portion.

In other words, when the fan 42 rotates in the first rotating direction, air outside the housing 10 is taken from the second ventilation portion 22. The heat sink 40 is cooled by the outside air taken from the second ventilation portion 22. The heat radiated from the heat sink 40 to the air inside the duct 43 is discharged upwardly (outside) from the housing 10 via the first ventilation portion 21 together with wind generated by the natural convection and the fan 42.

On the other hand, if the housing 10 is longitudinally installed, the angle sensor 30 senses the installation condition of the housing 10 and transmits the information to the control circuit 12. The control circuit 12 rotates the fan 42 in the second rotating direction such that the air inside the duct 43 flows in the second air-blowing direction (e.g., the direction represented by the arrow Y in FIG. 9). In this case, the first ventilation portion 21 serves as the air inlet portion and the second ventilation portion 22 serves as the exhaust portion.

In other words, when the fan 42 rotates in the second rotating direction, air outside the housing 10 is taken from the first ventilation portion 21. The heat sink 40 is cooled by the outside air taken from the first ventilation portion 21. The heat radiated from the heat sink 40 to the air inside the duct 43 is discharged upwardly (outside) from the housing 10 via the second ventilation portion 22 together with wind generated by the natural convection and the fan 42.

In the main unit 2, the air heated by the heat emitted from the CPU 14 flows inside the duct 43 and is discharged outside the housing 10 since the CPU 14 is provided inside the duct 43. Therefore, a number of circuit components mounted on the circuit board 13 and the function components provided inside the housing 10 are hardly influenced by the heat emitted from the CPU 14.

If the temperature in the vicinity of the CPU 14 is lower than a predetermined temperature, rotation of the fan 42 may be stopped. The heat emitted from the CPU 14 is transmitted to the heat sink 40 and is radiated into air. The air thus heated flows inside the duct 43 by the natural convection such that the heat of the air is radiated outside the housing 10 through the first ventilation portion 21 or the second ventilation portion 22.

In summary, according to the computer 1, as described above, when the housing 10 of the main unit 2 is transversely installed, the air flow is forcefully routed in the first air-blowing direction, namely in the direction from the second ventilation portion 22 provided on the right sidewall 11c to the first ventilation portion 21 provided on the top wall 11b. When the housing 10 is longitudinally installed, the air flow is forcefully routed in the second air-blowing direction, such as in the direction from the first ventilation portion 21 provided on the top wall 11b to the second ventilation portion 22 provided on the right sidewall 11c for example, by the fan 42 serving as the air-blowing unit. Thus, if the housing 10 is installed transversely or longitudinally, the air inside the housing 10 can be made to flow from the lower side to the upper side. Therefore, if the installation condition of the housing 10 is changed, the heat emitted from the CPU 14 can be radiated outside the housing 10.

The main unit 2 comprises the duct 43 which makes the first ventilation portion 21 and the second ventilation portion 22 communicate with each other, inside the housing 10. The CPU 14 is provided inside the duct 43. For this reason, the heat emitted from the CPU 14 is made to flow together with the air inside the duct 43. Therefore, a number of circuit components mounted on the circuit board 13 and the function components provided in the housing 10 are hardly influenced by the heat emitted from the CPU 14.

The air-blowing unit comprises the fan 42. The fan 42 is rotational in the first rotating direction to blow air in the first air-blowing direction or the second rotating direction to blow air in the second air-blowing direction. For this reason, air inside the housing 10 (duct 43 of the computer 1) can be made to flow in the first or second air-blowing direction.

The control circuit 12 controls the fan 42 to rotate in the first rotating direction when the housing 10 is in the transversely installed implementation and to rotate in the second rotating direction when the housing 10 is in the longitudinally installed implementation. The main unit 2 comprises the angle sensor 30 configured to determine the implementation of the housing 10, namely whether the housing 10 is transversely installed or longitudinally installed. The control circuit 12 controls the rotating direction of the fan 42 on the basis of the information about the implementation sensed by the angle sensor 30. Therefore, even if the housing 10 is installed transversely or longitudinally, the air heated by the heat of the CPU 14 can be discharged upward to the outside the housing 10 without urging the user using the computer 1 to spend much effort.

A second embodiment of the present invention will be described below with reference to FIG. 10.

In the computer 1, once the main unit 2 and the display 3 are installed their positions are rarely changed. For this reason, in the main unit 2 of the computer 1 according to the second embodiment, an operation unit 50 is provided to enable the user to manually set the implementation of the computer 1. The operation unit 50 is configured to produce a signal based on a manual event signaling change of the rotating direction of the fan 42 and the angle sensor 30 is omitted. The signal to change the rotating direction of the fan 42 is prompted by pushing a button 50a can be employed as the operation unit 50.

The operation unit 50 is provided inside the housing 10. The operation unit 50 is exposed to the outside through the housing 10. To describe in detail, an opening portion 51 is provided on the right sidewall 11c of the housing 10 and is adjacent to the first ventilation portion 21. The opening portion 51 is great enough to prevent a finger of the user using the computer 1 from entering the opening portion 51. The operation unit 50 is provided opposite to the opening portion 51, inside the housing 10. In other words, the operation unit 50 is provided adjacent to the fan 42. The operation unit 50 is electrically connected to the control circuit 12. The other constituent elements including elements not shown in the figure are the same as those of the first embodiment. They are denoted by the same reference numerals and their explanation is omitted.

In the computer 1, when the main unit 2 and the display 3 are arranged, the operation unit 50 may be operated to rotate the fan 42 in the direction suitable for the arrangement. It is assumed that, in an initial state, the fan 42 is set to rotate in the first rotating direction (e.g., the direction of blowing the air inside the duct 43 in the first air-blowing direction). When the main unit 2 is in the transversely installed implementation, it may be used as it is. If the temperature in the vicinity of the CPU 14 is equal to or higher than a predetermined temperature, the fan 42 rotates in the first rotating direction.

When the main unit 2 is in the longitudinally installed implementation, a narrow rod 52 such as a nib is inserted into the opening portion 51 to push (operate) the button 50a of the operation unit 50. If the operation unit 50 is operational, a signal is transmitted to the control circuit 12 such that the control circuit 12 changes the rotating direction of the fan 42. Thus, the fan 42 is now controlled to rotate in the second rotating direction (e.g. the direction of blowing the air inside the duct 43 in the second air-blowing direction). After that, if the temperature in the vicinity of the CPU 14 is equal to or higher than a predetermined temperature, the fan 42 rotates in the second rotating direction.

When the implementation of the main unit 2 is changed from the longitudinally installed implementation to the transversely installed implementation, the operation unit 50 may be operated. Upon depression of the button 50a, the signal is transmitted to the control circuit 12 such that the control circuit 12 changes the rotating direction of the fan 42. Thus, the fan 42 rotates in the first rotating direction. After that, if the temperature in the vicinity of the CPU 14 is equal to or higher than a predetermined temperature, the fan 42 rotates in the first rotating direction. When the implementation of the main unit 2 is changed again from the transversely installed implementation to the longitudinally installed implementation, the same operation may be performed.

In general, the angle sensor 30 is often expensive. If the angle sensor 30 is employed as the means for automatically determining the implementation of the housing 10, the computer 1 can be expensive. For this reason, if the angle sensor 30 is omitted, the main unit 2 can be produced at a low cost.

Once the main unit 2 and the display 3 are installed, generally, their positions are rarely changed. For this reason, even if the signal to change the rotating direction of the fan 42 is manually input, the user is not urged to spend much effort.

According to the computer 1 of this embodiment, as described above, since the operation unit 50 is provided to manually input the signal changing the rotating direction of the fan 42, the angle sensor 30 can be omitted. Therefore, the computer 1 can be produced at a low cost. In addition, when the rotating direction of the fan 42 is changed, the operation unit 50 alone needs to be operated. As a result, the user does not need to spend much effort to change the rotating direction of the fan 42.

In the computer 1, the operation unit 50 is provided inside the housing 10. For this reason, the user of the computer 1 or the like hardly touches the operation unit 50 in error. In other words, operation errors of the operation unit 50 can be reduced in the computer 1.

Moreover, the operation unit 50 is exposed to the outside through the housing 10. For this reason, the operation unit 50 can be operated from the outside of the housing 10 though the operation unit 50 is provided inside the housing 10. The operation unit 50 can be easily operated in the computer 1.

A third embodiment of the present invention will be described below with reference to FIG. 11.

In the main unit 2 of the computer 1 according to this embodiment, the fan 42 capable of rotating in a single direction is provided in the housing 10 so as to be easily detachable therefrom and the angle sensor 30 or the operation unit 50 is omitted.

To describe in detail, the fan 42 is supported by the supporting member 18 provided on the inner surface of the right sidewall 11c so as to be easily detachable therefrom. Thus, the fan 42 can be attached in a first attachment direction to blow air in the first air-blowing direction (e.g., the direction of blowing air from the second ventilation portion 22 side to the first ventilation portion 21 side) or a second attachment direction to blow air in the second air-blowing direction (e.g., the direction of blowing air from the first ventilation portion 21 side to the second ventilation portion 22 side). In other words, the fan 42 can be turned upside down and attached to the housing 10 after changing the direction of blades of the fan 42.

Incidentally, if the fan 42 is turned upside down, the extending direction of the cable 45 provided at the fan 42 is changed. For this reason, the main unit 2 comprises two connectors 44a and 44b for supply of power to the fan 42 at a front end (one of ends) and a rear end (other end) of the fan 42, respectively. Thus, the plug of the cable 45 of the fan 42 can be inserted into the connector 44a or 44b without changing the length of the cable 45.

Furthermore, if the housing 10 is formed of the base portion comprising the bottom wall 11a and the cover comprising the top wall 11b, right sidewall 11c, left sidewall 11d, front wall 11e and rear wall 11f, the mounting area can be opened. The other constituent elements including elements not shown in the figure are the same as those of the first embodiment. They are denoted by the same reference numerals in the figure and their explanation is omitted.

In the computer 1, when the main unit 2 and the display 3 are arranged, the fan 42 may be attached such that the rotating direction of the fan 42 is suitable for the arrangement of the housing 10. In other words, when the fan 42 is attached to blow the air inside the duct 43 in the first air-blowing direction, in the initial state, the implementation of the main unit 2 does not need to be changed if the main unit 2 in the transversely installed implementation is used.

If the implementation of the main unit 2 is changed to the longitudinally installed implementation, the mounting area of the housing 10 is opened and the plug is detached from the connector 44a. Then, the fan 42 is detached from the housing 10, turned upside down and attached to the housing 10 via supporting member 18. The plug is inserted into the connector 44b and the housing 10 is returned to the initial state (i.e. the mounting area is covered). Thus, the air inside the dust 43 is blown in the second air-blowing direction by the fan 42.

If the longitudinally installed implementation of the main unit 2 is changed to the transversely installed implementation, the mounting area of the housing 10 is opened and the plug is detached from the connector 44b. Then, the fan 42 is detached from the housing 10, turned upside down and attached to the housing 10. The plug is inserted into the connector 44a and the housing 10 is returned to the initial state. Thus, the air inside the dust 43 is blown in the first air-blowing direction by the fan 42. The same operations are performed if the transversely installed implementation of the main unit 2 is changed to the longitudinally installed implementation.

According to the computer 1, as described above, the fan 42 capable of rotating in a single direction can be turned upside down and attached to the housing 10. Even if the angle sensor 30 and the operation unit 50 are omitted, the same advantage as that of the first or second embodiment can be obtained. In addition, the computer 1 of this embodiment can be produced at a lower cost than the computer 1 of the first embodiment comprising the angle sensor 30 and the fan 42 capable of rotating in both the normal direction and the backward direction and the computer 1 of the second embodiment comprising the operation unit 50 and the fan 42 capable of rotating in both the normal direction and the backward direction.

In the above-described first to third embodiments, the second wall on which the second ventilation portion 22 is the right sidewall 11c in the transversely installed state. However, even if the second wall is the left sidewall 11d, rear wall 11f or the like in the transversely installed state, the same advantage can be obtained.

The present invention is not limited to the embodiments described above and can be modified in various manners without departing from the spirit and scope of the invention.

1. An electronic apparatus comprising:
a housing comprises a first wall including a first ventilation portion and a second wall including a second ventilation portion and extending in a direction to intersect the first wall, the housing capable of being installed in a first state allowing the first wall to face upward and a second state allowing the second wall to face upward; and
an air-blowing unit configured to (i) route a flow of air in a first direction from a side of the second ventilation portion to a side of the first ventilation portion when the housing is in the first state, and (ii) route the flow of air in a second direction from the side of the first ventilation portion to the side of the second ventilation portion when the housing is in the second state.

2. The electronic apparatus according to claim 1, wherein each of the first and second ventilation portions includes ventilation apertures.

3. The electronic apparatus according to claim 1, further comprising a duct that enables routing of the flow of air between the first ventilation portion and the second ventilation portion.

4. The electronic apparatus according to claim 3, further comprising a heat-generating unit being provided within the duct.

5. The electronic apparatus according to claim 3, wherein the housing is for a computer.

6. The electronic apparatus according to claim 1, wherein the air-blowing unit includes a fan.

7. The electronic apparatus according to claim 6, wherein the fan is freely rotational in a first rotating direction to route the flow of air in the first direction and in a second rotating direction to route the flow of air in the second direction.

8. The electronic apparatus according to claim 7 further comprising a control unit configured to control a selected rotating direction of the fan, the fan being controlled to rotate in the first rotating direction when the housing is in the first state and to rotate in the second rotating direction when the housing is in the second state.

9. The electronic apparatus according to claim 8 further comprising an angle sensor in communication with the control unit, the angle sensor being configured to discriminate between the first state and the second state based on information sensed by the angle sensor.

10. The electronic apparatus according to claim 7 further comprising an operation unit configured to change the rotating direction of the fan in response to a manual event performed on the operation unit.

11. The electronic apparatus according to claim 10, wherein the operation unit is provided inside the housing and is exposed outside through an opening portion within the housing.

12. The electronic apparatus according to claim 6, wherein the fan is freely rotational in a single direction, and can be attached in a first attachment direction to blow air in the first direction and a second attachment direction to blow air in the second direction.

13. An electronic apparatus comprising:
a housing comprises a plurality of walls including a first wall coupled to a second wall, the first wall including a first ventilation portion and the second wall including a second ventilation portion; and
a fan situated inside the housing, the fan configured to (i) route a flow of air in a first direction from the second ventilation portion to the first ventilation portion when the housing is placed in a first state with the first wall facing upward, and (ii) route the flow of air in a second direction from the first ventilation portion to the second ventilation portion when the housing is in a second state with the second wall facing upward.

14. The electronic apparatus according to claim 13 further comprising a duct that enables routing of the flow of air between the first ventilation portion and the second ventilation portion.

15. The electronic apparatus according to claim 14 further comprising a heat-generating unit positioned within the duct.

16. The electronic apparatus according to claim 13, wherein the housing is for a computer.

17. The electronic apparatus according to claim 13, wherein the fan is freely rotational in a first rotating direction to route the flow of air in the first direction and in a second rotating direction opposite the first rotating direction to route the flow of air in the second direction.

18. The electronic apparatus according to claim 17 further comprising a control unit configured to control a selected rotating direction of the fan, the fan being controlled to rotate in the first rotating direction when the housing is in the first state and to rotate in the second rotating direction when the housing is in the second state.

19. The electronic apparatus according to claim 18 further comprising an angle sensor in communication with the control unit, the angle sensor being configured to discriminate between the first state and the second state based on information sensed by the angle sensor.

20. The electronic apparatus according to claim 13 further comprising an operation unit controlling the rotating direction of the fan, a portion of the operation unit being exposed for manual selection by a user.

21. The electronic apparatus according to claim 13, wherein the fan is freely rotational in a single direction and is detachable from the housing, the fan is attached in a first attachment direction to route air in the first direction and in a second attachment direction to route air in the second direction.

22. A computer comprising:
a housing formed by a plurality of walls, a first wall of the plurality of walls includes a first ventilation portion and a second wall of the plurality of walls includes a second ventilation portion; and
a fan situated within the housing an attached to an interior of at least one of the plurality of walls, the fan configured to alter a direction of a flow of air based on how the housing is situated.

23. The computer according to claim 22, wherein the fan routes the flow of air in a first direction from the second ventilation portion to the first ventilation portion when the housing is placed in a first state, and routes the flow of air in a second direction from the first ventilation portion to the second ventilation portion when the housing is in a second state.

24. The computer according to claim 23, wherein the housing is in the first state when the first wall is facing upward and is in the second state when the second wall facing upward.
